(19) United States
(12) Patent Application Publication
(10) Pub. No.: US 2024/0128282 A1
(43) Pub. Date: Apr. 18, 2024

(54) SEMICONDUCTOR DEVICE, ELECTRONIC DEVICE, AND METHOD OF CONTROLLING SEMICONDUCTOR DEVICE

(71) Applicant: Sony Semiconductor Solutions Corporation, Kanagawa (JP)

(72) Inventors: Koichi Okamoto, Kanagawa (JP); Hideaki Mogi, Kanagawa (JP); Takashi Masuda, Tokyo (JP); Shinichirou Saeki, Kanagawa (JP); Mitsushi Tabata, Kanagawa (JP)

(21) Appl. No.: 18/279,148

(22) PCT Filed: Feb. 16, 2022
(86) PCT No.: PCT/JP2022/006038

§ 371 Date: Aug. 28, 2023

(30) Foreign Application Priority Data
Mar. 30, 2021 (JP) 2021-058632

(51) Int. Cl. H01L 27/146; H01S 5/068

(52) U.S. Cl. CPC H01L 27/14601; H01S 5/068

(57) ABSTRACT

A semiconductor device (10) according to one aspect of the present disclosure includes: a driving section (40) that drives an object to be driven; an abnormality detecting circuit (30), which is one example of an instruction circuit that outputs an instruction signal to the driving section (40); and a light amount detecting section (20) that detects an amount of incident light and invalidates the instruction signal output from the abnormality detecting circuit (30) in accordance with the amount of incident light.

### FIELD

The present disclosure relates to a semiconductor device, an electronic device, and a method of controlling the semiconductor device.

### BACKGROUND

Normally, when light (visible light to infrared light) enters a junction portion (for example, PN junction) of a semiconductor device, current is generated by photoelectric conversion. Therefore, when light enters a junction portion of an integrated circuit (IC), circuit characteristics fluctuate. For example, in an IC (laser drive in an example) with safety standard restriction, package technology for preventing light from entering the IC is used since the characteristic fluctuation due to photoelectric conversion has a significant influence. It may be, however, difficult to apply the package technology such as fan-out packaging from the viewpoint of chip structure, size, cost, and the like.

### CITATION LIST

### Patent Literature

Patent Literature 1: JP 2009-43784 A

### SUMMARY

### Technical Problem

For example, in relation to semiconductor devices, semiconductor devices mounted with a circuit constituting an abnormality detecting circuit, a current control circuit (for example, auto power control (APC)), and the like, that is, an instruction circuit that gives various instructions have been developed (for example, see Patent Literature 1). In such a semiconductor device, characteristics of an instruction circuit may fluctuate due to light incident on a junction portion. If the characteristic fluctuation causes a malfunction of the instruction circuit, control is performed in accordance with the malfunction of the instruction circuit.

Therefore, the present disclosure proposes a semiconductor device, an electronic device, and a method of controlling the semiconductor device capable of inhibiting execution of control in accordance with a malfunction of an instruction circuit.

### Solution to Problem

A semiconductor device according to the embodiment of the present disclosure includes: a driving section that drives an object to be driven; an instruction circuit that outputs an instruction signal to the driving section; and a light amount detecting section that detects an amount of incident light, and invalidates the instruction signal output from the instruction circuit in accordance with the amount of incident light.

An electronic device according to the embodiment of the present disclosure includes: a solid-state imaging device; and a semiconductor device, wherein the semiconductor device includes: a driving section that drives an object to be driven; an instruction circuit that outputs an instruction signal to the driving section; and a light amount detecting section that detects an amount of incident light, and invalidates the instruction signal output from the instruction circuit in accordance with the amount of incident light.

A method of controlling a semiconductor device, according to the embodiment of the present disclosure includes: detecting an amount of incident light; and invalidating an instruction signal output from an instruction circuit to a driving section that controls an object to be driven in accordance with the amount of incident light which has been detected.

### BRIEF DESCRIPTION OF DRAWINGS

FIG. 1 illustrates an example of a schematic configuration of a semiconductor device according to a first embodiment.

FIG. 2 is a first view illustrating an example of a schematic structure of the semiconductor device according to the first embodiment.

FIG. 3 is a second view illustrating an example of the schematic structure of the semiconductor device according to the first embodiment.

FIG. 4 is a first view illustrating an example of a schematic structure of a semiconductor device according to a second embodiment.

FIG. 5 is a second view illustrating an example of the schematic structure of the semiconductor device according to the second embodiment.

FIG. 6 is a first view illustrating an example of a schematic structure of a semiconductor device according to a third embodiment.

FIG. 7 is a second view illustrating an example of the schematic structure of the semiconductor device according to the third embodiment.

FIG. 8 is a first view illustrating an example of a schematic structure of a semiconductor device according to a fourth embodiment.

FIG. 9 is a second view illustrating an example of the schematic structure of the semiconductor device according to the fourth embodiment.

FIG. 10 is a first view illustrating an example of a schematic structure of a semiconductor device according to a fifth embodiment.

FIG. 11 is a second view illustrating an example of the schematic structure of the semiconductor device according to the fifth embodiment.

FIG. 12 illustrates an example of a schematic structure of a semiconductor device according to a sixth embodiment.

FIG. 13 illustrates an example of a schematic structure of a semiconductor device according to a seventh embodiment.

FIG. 14 illustrates an example of a schematic configuration of a distance measuring device.

FIG. 15 illustrates an example of a schematic configuration of an imaging device.

FIG. 16 is a block diagram depicting an example of schematic configuration of a vehicle control system.

FIG. 17 is a diagram of assistance in explaining an example of installation positions of an outside-vehicle information detecting section and an imaging section.

### DESCRIPTION OF EMBODIMENTS

Embodiments of the present disclosure will be described in detail below with reference to the drawings. Incidentally, a device, an apparatus, a method, and the like according to the present disclosure are not limited by the embodiments. In addition, in each of the following embodiments, basically, the same reference signs are attached to the same parts, and duplicate description is omitted.

One or a plurality of embodiments (including examples and variations) to be described below can be implemented independently. In contrast, at least a part of the plurality of embodiments to be described below may be appropriately combined with at least a part of other embodiments. The plurality of embodiments may include different novel features. Therefore, the plurality of embodiments may contribute to solving different objects or problems, and may exhibit different effects.

The present disclosure will be described in the following item order.
1. First Embodiment
1-1. Example of Schematic Configuration of Semiconductor Device
1-2. Example of Schematic Structure of Semiconductor Device
1-3. Actions/Effects
2. Second Embodiment
2-1. Example of Schematic Structure of Semiconductor Device
2-2. Actions/Effects
3. Third Embodiment
3-1. Example of Schematic Structure of Semiconductor Device
3-2. Actions/Effects
4. Fourth Embodiment
4-1. Example of Schematic Structure of Semiconductor Device
4-2. Actions/Effects
5. Fifth Embodiment
5-1. Example of Schematic Structure of Semiconductor Device
5-2. Actions/Effects
6. Sixth Embodiment
6-1. Example of Schematic Structure of Semiconductor Device
6-2. Actions/Effects
7. Seventh Embodiment
7-1. Example of Schematic Structure of Semiconductor Device
7-2. Actions/Effects
8. Other Embodiments
9. Application Examples
9-1. Distance Measuring Device
9-2. Imaging Device
10. Application Examples
11. Appendix

### 1. FIRST EMBODIMENT

<1-1. Example of Schematic Configuration of Semiconductor Device>

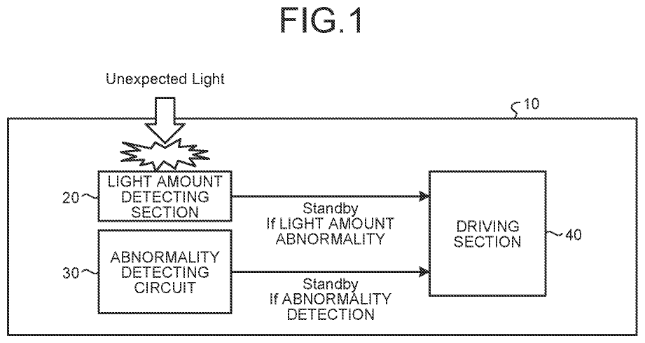

An example of a schematic configuration of a semiconductor device 10 according to an embodiment will be described with reference to FIG. 1. FIG. 1 illustrates an example of the schematic configuration of the semiconductor device 10 according to the embodiment.

As illustrated in FIG. 1, the semiconductor device 10 includes a light amount detecting section 20, an abnormality detecting circuit 30, and a driving section 40. Examples of the driving section 40 include a semiconductor laser driver that controls a semiconductor laser to be driven.

The light amount detecting section 20 detects light (for example, ambient light, which is light that has not been expected) incident on the semiconductor device 10. When an amount of the incident light exceeds a predetermined value, the light amount detecting section 20 outputs a standby instruction signal (waiting instruction signal) to the driving section 40. For example, the light amount detecting section 20 determines whether or not the amount of the incident light is larger than the predetermined value. When the light amount is larger than the predetermined value, the light amount detecting section 20 outputs the standby instruction signal to the driving section 40. In contrast, when the light amount is equal to or less than the predetermined value, the light amount detecting section 20 does not output the standby instruction signal to the driving section 40. The predetermined value is preliminarily set to a limit value or less of a light amount for the light amount detecting section 20 in order to prevent a malfunction of the abnormality detecting circuit 30 due to incident light, for example.

The abnormality detecting circuit 30 detects a temperature of an object to be driven (for example, semiconductor laser). When the temperature exceeds a predetermined value, the abnormality detecting circuit 30 outputs the standby instruction signal to the driving section 40. For example, the abnormality detecting circuit 30 determines whether or not the temperature is higher than the predetermined value. When the temperature is higher than the predetermined value (abnormally high temperature), the abnormality detecting circuit 30 outputs the standby instruction signal to the driving section 40. In contrast, when the temperature is equal to or less than the predetermined value, the abnormality detecting circuit 30 does not output the standby signal to the driving section 40. The predetermined value is preliminarily set for the abnormality detecting circuit 30 in order to prevent a failure of an object to be driven due to the temperature, for example. Incidentally, in addition to the temperature, various values such as a current value and a voltage value can be adopted as objects to be detected. The abnormality detecting circuit 30 corresponds to an instruction circuit.

In the abnormality detecting circuit 30, characteristics fluctuate due to a certain amount of incident light. That is, it is necessary to inhibit influences of incident light such as ambient light in the abnormality detecting circuit 30. In addition to the temperature abnormality detecting circuit that detects a temperature abnormality of an object to be driven, a circuit that detects an abnormal current and an abnormal voltage of the object to be driven (for example, abnormal current detecting circuit and abnormal voltage detecting circuit) may be used as the abnormality detecting circuit 30. That is, for example, an abnormality detecting circuit that detects an abnormality related to any of temperature, current, and voltage may be used as the abnormality detecting circuit 30. The abnormality detecting circuit 30 functions as a protection circuit.

Incidentally, in addition to the abnormality detecting circuit 30, for example, a current control circuit that controls a current (drive current) flowing through an object to be driven such as a semiconductor laser may be used. For example, the current control circuit controls and limits the current flowing through an object to be driven so that the current constantly flows. The current control circuit also corresponds to the instruction circuit. In addition, a control circuit that controls voltage, temperature, and the like in addition to current may be used. That is, for example, a control circuit that controls any of current, voltage, and temperature may be used as the instruction circuit.

The driving section 40 is a driving circuit that drives an object to be driven (for example, semiconductor laser). For example, the driving section 40 supplies a drive current to the object to be driven. In addition, the driving section 40 sets a driving operation into a standby state (waiting state) in response to a standby instruction signal output from the light amount detecting section 20. Further, the driving section 40 sets the driving operation into a standby state in response to a standby instruction signal output from the abnormality detecting circuit 30. Here, the driving section 40 sets the driving operation into the standby state and stops the driving operation in response to the standby instruction signal output from the light amount detecting section 20. Thus, when an amount of incident light exceeds a predetermined value, the driving section 40 can invalidate the standby instruction signal output from the abnormality detecting circuit 30. This can inhibit the driving section 40 from performing the driving operation in accordance with a malfunction of the abnormality detecting circuit 30 due to incident light.

Incidentally, in addition to invalidating the standby instruction signal output from the abnormality detecting circuit 30 by setting the driving section 40 into the standby state, the standby instruction signal output from the abnormality detecting circuit 30 may be invalidated by, for example, providing a switching section (not illustrated), such as a switch, that switches connection/disconnection (ON/OFF) of wiring connected from the abnormality detecting circuit 30 to the driving section 40 and controlling the switching section to disconnect the wiring. For example, various transistors are used as the switch.

<1-2. Example of Schematic Structure of Semiconductor Device>

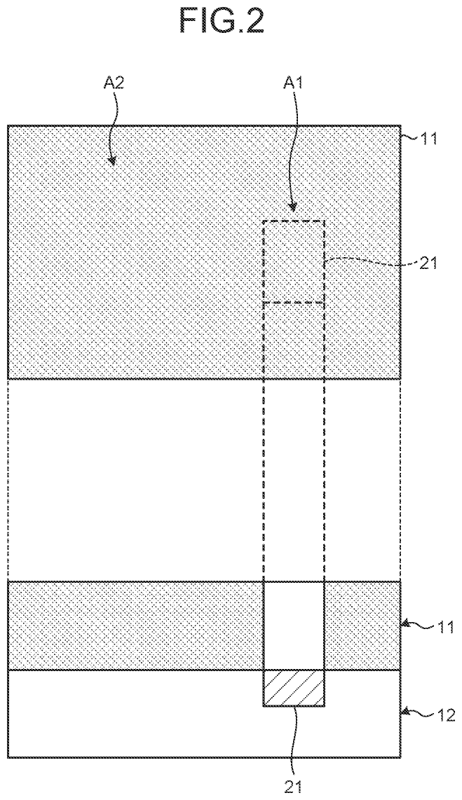

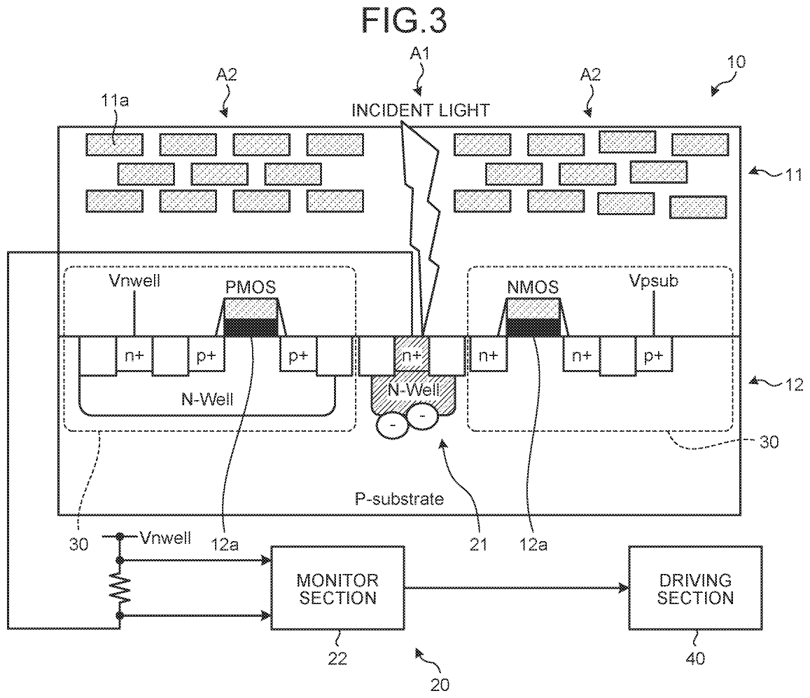

An example of a schematic structure of the semiconductor device 10 according to the embodiment will be described with reference to FIGS. 2 and 3. FIGS. 2 and 3 each illustrate the example of the schematic structure of the semiconductor device 10 according to the embodiment. In the example of FIG. 3, an upper diagram is a plan view of the semiconductor device 10, and a lower diagram is a cross-sectional view of the semiconductor device 10.

As illustrated in FIGS. 2 and 3, the semiconductor device 10 includes a wiring layer 11 and an element layer 12. The wiring layer 11 is stacked on the element layer 12.

The wiring layer 11 includes various pieces of wiring 11a (see FIG. 3) and an insulating portion. The wiring layer 11 includes a sparse region A1 and a dense region A2. The sparse region A1 is a portion having sparse wiring 11a. The dense region A2 is a portion having dense wiring 11a. Various pieces of wiring 11a are arranged in a planar direction so as not to be in contact with each other, and stacked in a thickness direction.

The element layer 12 includes various elements 12a (see FIG. 3). Examples of these elements 12a include transistors such as a negative-channel metal oxide semiconductor (NMOS) and a positive-channel metal oxide semiconductor (PMOS) and various circuit elements. The element layer 12 includes various circuit elements constituting the abnormality detecting circuit 30, that is, the abnormality detecting circuit 30. The abnormality detecting circuit 30 is provided below (for example, immediately below) the dense region A2 of the wiring layer 11. This makes it difficult for incident light such as ambient light to reach the abnormality detecting circuit 30, so that the malfunction of the abnormality detecting circuit 30 can be inhibited. Examples of the element layer 12 include a semiconductor substrate.

The light amount detecting section 20 includes a photoelectric conversion section 21 (see FIGS. 2 and 3) and a monitor section 22 (see FIG. 3). The monitor section 22 corresponds to an observation section.

The photoelectric conversion section 21 performs photoelectric conversion of converting incident light into electricity. Examples of the photoelectric conversion section 21 include a photoelectric conversion element such as a PN junction photodiode. For example, the photoelectric conversion section 21 is provided below (for example, immediately below) the sparse region A1 of the wiring layer 11. This makes it easy for incident light such as ambient light to reach the photoelectric conversion section 21, so that the incident light can be reliably detected.

In addition, the photoelectric conversion section 21 is provided at a position around the abnormality detecting circuit 30, for example, at a position adjacent to the abnormality detecting circuit 30. In the example of FIG. 3, the photoelectric conversion section 21 is provided at a position adjacent to and sandwiched between elements constituting the abnormality detecting circuit 30. This enables the incident light such as ambient light influencing the abnormality detecting circuit 30 to be reliably detected.

The monitor section 22 observes the voltage (or current) of the photoelectric conversion section 21. When a voltage value exceeds a predetermined value, the monitor section 22 outputs a standby instruction signal to the driving section 40. For example, the monitor section 22 determines whether or not the voltage value is larger than the predetermined value. When the voltage value is larger than the predetermined value, the monitor section 22 outputs the standby instruction signal to the driving section 40. In contrast, when the voltage value is equal to or less than the predetermined value, the monitor section 22 does not output the standby instruction signal to the driving section 40. The predetermined value is preliminarily set to a limit value or less of a light amount for the monitor section 22 in order to prevent a malfunction of the abnormality detecting circuit 30 due to incident light. Incidentally, in addition to the voltage value, various values such as a current value can be adopted as objects to be detected.

<1-3. Actions/Effects>

As described above, according to a first embodiment, the light amount detecting section 20 detects an amount of incident light (for example, ambient light). The light amount detecting section 20 invalidates an instruction signal (for example, event detection signal) output from an instruction circuit (for example, abnormality detecting circuit 30) to the driving section 40 in accordance with the detected amount of incident light. This can inhibit the driving section 40 from performing a driving operation in accordance with a malfunction of the instruction circuit due to incident light.

In addition, the light amount detecting section 20 may set the driving section 40 into the waiting state in accordance with the amount of incident light, and invalidate the instruction signal output from the instruction circuit. This enables the instruction signal to be invalidated by simple configuration.

In addition, the light amount detecting section 20 may include the photoelectric conversion section 21 that performs photoelectric conversion. The photoelectric conversion section 21 may be provided around the instruction circuit. This enables incident light influencing the instruction circuit to be reliably detected.

In addition, the photoelectric conversion section 21 may be provided at a position adjacent to the instruction circuit. This enables incident light influencing the instruction circuit to be more reliably detected.

In addition, the wiring layer 11 including the sparse region A1, which is a portion having sparse wiring 11a, may be further provided. The light amount detecting section 20 may include the photoelectric conversion section 21 that performs photoelectric conversion. The photoelectric conversion section 21 may be provided below the sparse region A1. This makes it easy for incident light to reach the photoelectric conversion section 21, so that the incident light can be reliably detected.

In addition, the element layer 12 including an instruction circuit may be further provided. The photoelectric conversion section 21 may be provided in the element layer 12 below the sparse region A1. This enables various elements 12a of the element layer 12 and the photoelectric conversion section 21 to be formed in the same process, so that the number of processes and a manufacturing time can be reduced.

In addition, the wiring layer 11 including the dense region A2, which is a portion having dense wiring 11a, may be further provided. The instruction circuit may be provided below the dense region A2. This makes it difficult for incident light to reach the instruction circuit, so that a malfunction of the instruction circuit can be inhibited.

In addition, the light amount detecting section 20 may include the photoelectric conversion section 21 and the monitor section 22. The photoelectric conversion section 21 performs photoelectric conversion. The monitor section 22 observes current generated by the photoelectric conversion section 21. This can implement the light amount detecting section 20 by simple configuration. Incidentally, observing current also means observing voltage, and is included in the concept.

In addition, the driving section 40 may drive a semiconductor laser, which is an object to be driven. This can inhibit the driving section 40 from performing a driving operation of the semiconductor laser in accordance with a malfunction of the instruction circuit due to incident light.

In addition, the instruction circuit may be the abnormality detecting circuit 30 that detects an abnormality related to any of temperature, current, and voltage. This can inhibit the driving section 40 from performing the driving operation in accordance with a malfunction of the abnormality detecting circuit 30 due to incident light.

In addition, the instruction circuit may be a control circuit that controls any of temperature, current, and voltage. This can inhibit the driving section 40 from performing a driving operation in accordance with a malfunction of the control circuit due to incident light.

### 2. SECOND EMBODIMENT

<2-1. Example of Schematic Structure of Semiconductor Device>

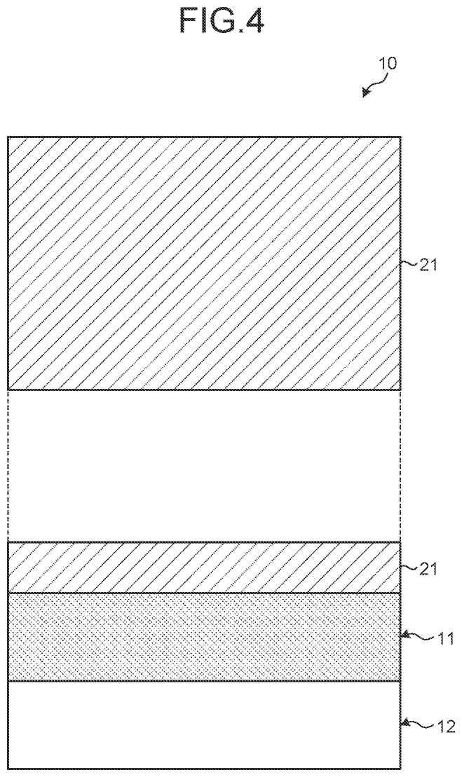

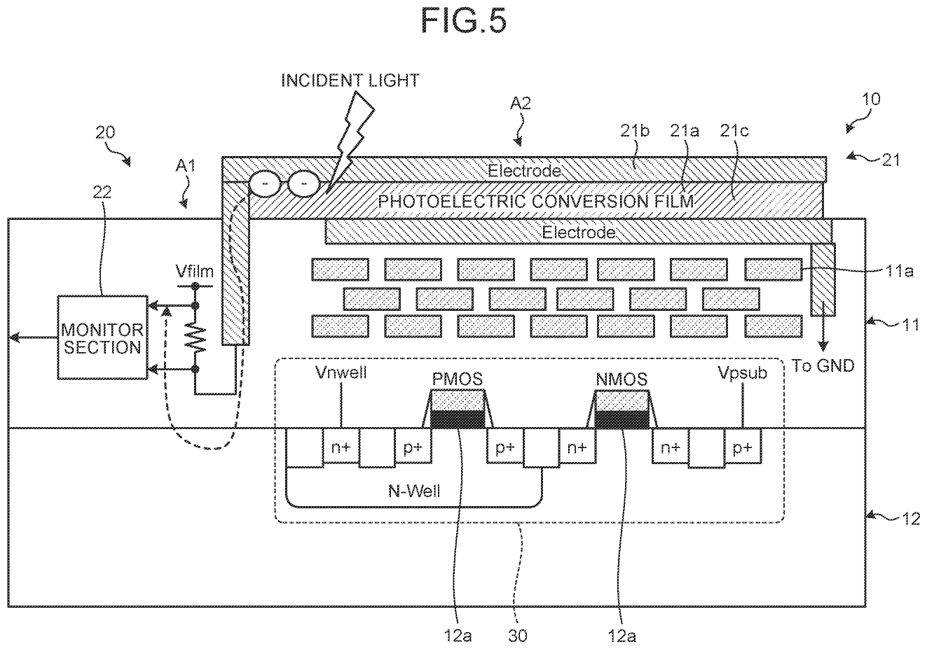

An example of a schematic structure of the semiconductor device 10 according to the embodiment will be described with reference to FIGS. 4 and 5. FIGS. 4 and 5 each illustrate the example of the schematic structure of the semiconductor device 10 according to the embodiment. Differences from the first embodiment will be mainly described below, and other descriptions will be omitted.

As illustrated in FIGS. 4 and 5, the photoelectric conversion section 21 is stacked on the wiring layer 11. As illustrated in FIG. 5, the photoelectric conversion section 21 is provided above the abnormality detecting circuit 30. Incidentally, the abnormality detecting circuit 30 is provided below (for example, immediately below) the dense region A2 of the wiring layer 11. In addition, the monitor section 22 is provided in the wiring layer 11.

As illustrated in FIG. 5, the photoelectric conversion section 21 includes a photoelectric conversion film 21a and a pair of electrode films 21b and 21c.

The photoelectric conversion film 21a performs photoelectric conversion. For example, an organic solar cell material is used for the photoelectric conversion film 21a.

The pair of electrode films 21b and 21c is disposed so as to sandwich the photoelectric conversion film 21a from the thickness direction (vertical direction in FIG. 5). The pair of electrode films 21b and 21c is in close contact with the photoelectric conversion film 21a, and applies voltage to the photoelectric conversion film 21a. The pair of electrode films 21b and 21c is formed of, for example, various conductive materials. In addition, examples of a material of the electrode film 21b include a light transmissive material. Examples of a material of an electrode film 21c include a light blocking material.

<2-2. Actions/Effects>

As described above, according to a second embodiment, effects similar to those of the first embodiment can be obtained. That is, the configuration according to the second embodiment can also inhibit the driving section 40 from performing a driving operation in accordance with a malfunction of the instruction circuit (for example, abnormality detecting circuit 30) due to incident light.

In addition, the wiring layer 11 including the wiring 11a may be further provided. The light amount detecting section 20 may include the photoelectric conversion section 21 that performs photoelectric conversion. The photoelectric conversion section 21 may be stacked on the wiring layer 11. This causes incident light to reliably reach the photoelectric conversion section 21, so that the incident light can be reliably detected.

In addition, the photoelectric conversion section 21 may include the photoelectric conversion film 21a and the pair of electrode films 21b and 21c. The photoelectric conversion film 21a performs photoelectric conversion. The pair of electrode films 21b and 21c is provided so as to sandwich the photoelectric conversion film 21a. The electrode film 21c on the side of wiring layer 11 among the pair of electrode films 21b and 21c may have light blocking property. The instruction circuit may be provided blow the photoelectric conversion section 21. This makes it difficult for incident light to reach the instruction circuit, so that a malfunction of the instruction circuit can be inhibited.

In addition, the wiring layer 11 including the wiring 11a may be further provided. The monitor section 22 may be provided in the wiring layer 11. This facilitates packaging of the semiconductor device 10.

### 3. THIRD EMBODIMENT

<3-1. Example of Schematic Structure of Semiconductor Device>

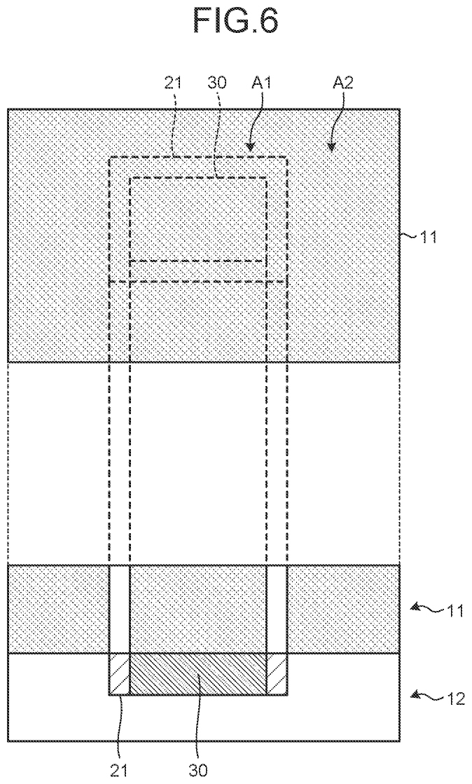

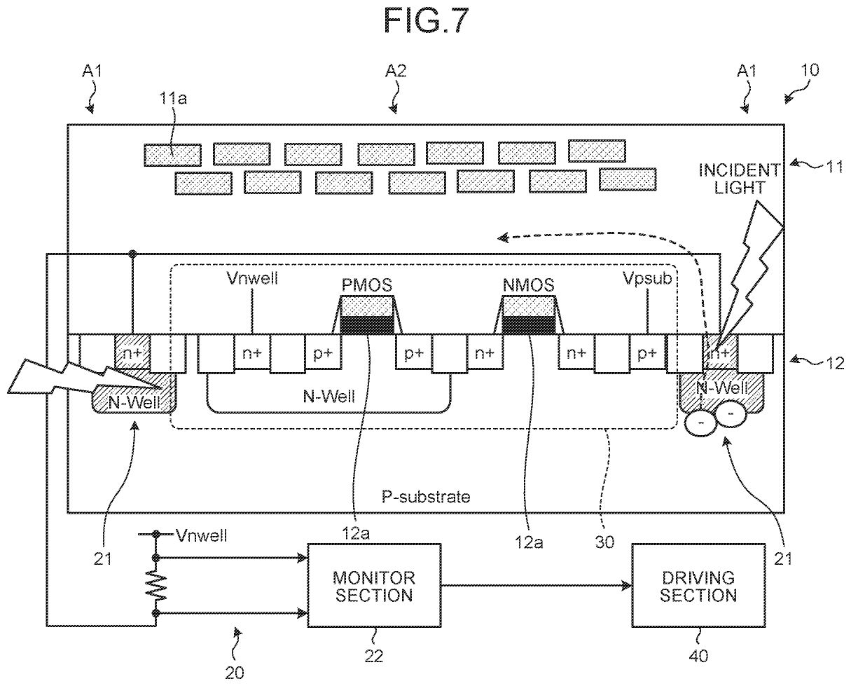

An example of a schematic structure of the semiconductor device 10 according to the embodiment will be described with reference to FIGS. 6 and 7. FIGS. 6 and 7 each illustrate the example of the schematic structure of the semiconductor device 10 according to the embodiment. Differences from the first embodiment will be mainly described below, and other descriptions will be omitted.

As illustrated in FIGS. 6 and 7, the photoelectric conversion section 21 is formed so as to surround the periphery of the abnormality detecting circuit 30, that is, the outer periphery of the abnormality detecting circuit 30. This can inhibit incident light such as ambient light from the outer periphery of the semiconductor device 10 from reaching the abnormality detecting circuit 30.

For example, the photoelectric conversion section 21 has an annular shape such as a rectangle. Incidentally, the shape of the photoelectric conversion section 21 is not limited to the annular shape of a rectangle. The photoelectric conversion section 21 may have another annular shape such as a polygon, an ellipse, and a circle, or may have a shape other than the annular shape.

<3-2. Actions/Effects>

As described above, according to a third embodiment, effects similar to those of the first embodiment can be obtained. That is, the configuration according to the third embodiment can also inhibit the driving section 40 from performing a driving operation in accordance with a malfunction of the instruction circuit (for example, abnormality detecting circuit 30) due to incident light.

In addition, the photoelectric conversion section 21 may be annularly formed so as to surround the outer periphery of the instruction circuit. This can inhibit incident light from the outer periphery of the semiconductor device 10 from reaching the instruction circuit, so that a malfunction of the instruction circuit can be reliably inhibited.

### 4. FOURTH EMBODIMENT

<4-1. Example of Schematic Structure of Semiconductor Device>

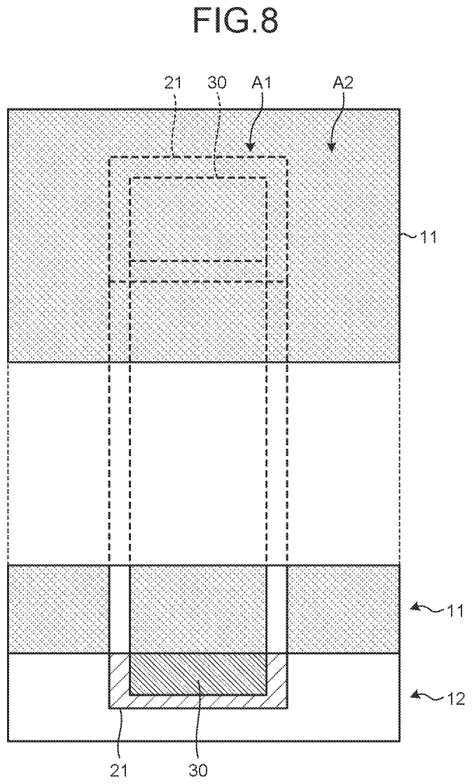

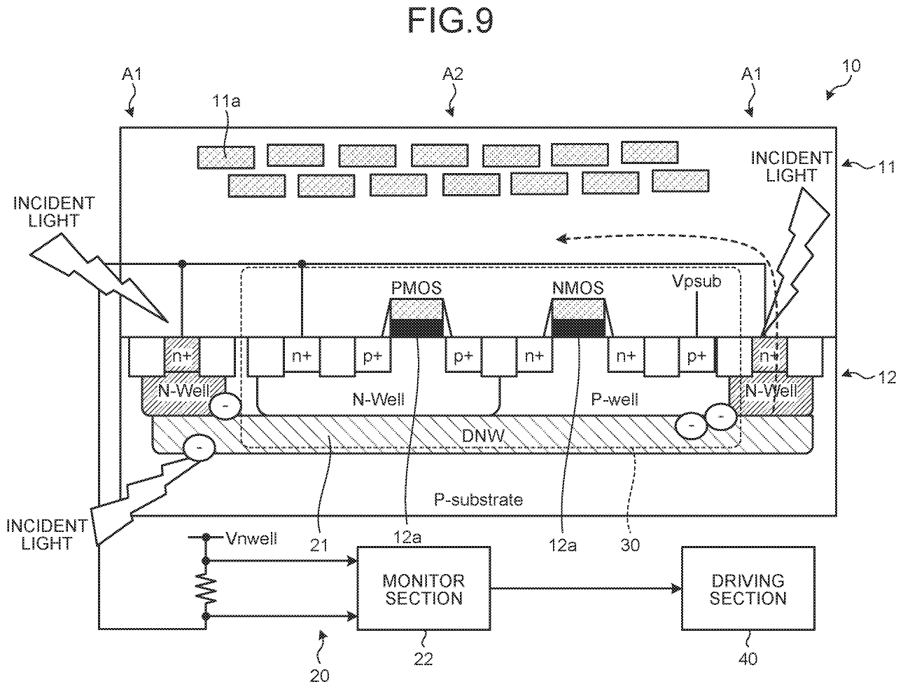

An example of a schematic structure of the semiconductor device 10 according to the embodiment will be described with reference to FIGS. 8 and 9. FIGS. 8 and 9 each illustrate the example of the schematic structure of the semiconductor device 10 according to the embodiment. Differences from the first embodiment will be mainly described below, and other descriptions will be omitted.

As illustrated in FIGS. 8 and 9, the photoelectric conversion section 21 is formed so as to cover the periphery of the abnormality detecting circuit 30, that is, the outer periphery of the abnormality detecting circuit 30, and a surface of the abnormality detecting circuit 30 on the side opposite to the wiring layer 11 (lower surface in FIGS. 8 and 9). This can inhibit incident light such as ambient light from the outer periphery of and below the semiconductor device 10 from reaching the abnormality detecting circuit 30.

For example, the photoelectric conversion section 21 has a box shape of a rectangle and the like (box shape with an open upper surface). Incidentally, the shape of the photoelectric conversion section 21 is not limited to the box shape of a rectangle. The photoelectric conversion section 21 may have another box shape such as a polygon, an ellipse, and a circle, or may have a shape other than the box shape.

<4-2. Actions/Effects>

As described above, according to a fourth embodiment, effects similar to those of the first embodiment can be obtained. That is, the configuration according to the fourth embodiment can also inhibit the driving section 40 from performing a driving operation in accordance with a malfunction of the instruction circuit (for example, abnormality detecting circuit 30) due to incident light.

In addition, the photoelectric conversion section 21 may be formed so as to cover the instruction circuit from below or above in addition to the outer periphery of the instruction circuit. This can inhibit incident light from the outer periphery of and below the semiconductor device 10 from reaching the abnormality detecting circuit 30, so that a malfunction of the instruction circuit can be reliably inhibited.

### 5. FIFTH EMBODIMENT

<5-1. Example of Schematic Structure of Semiconductor Device>

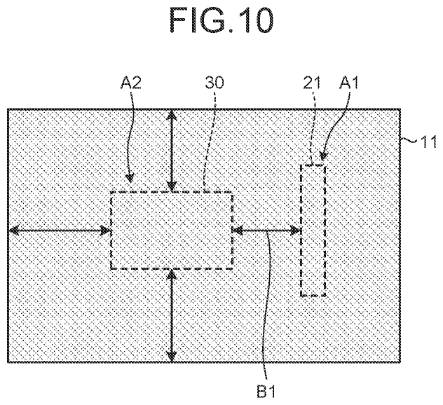

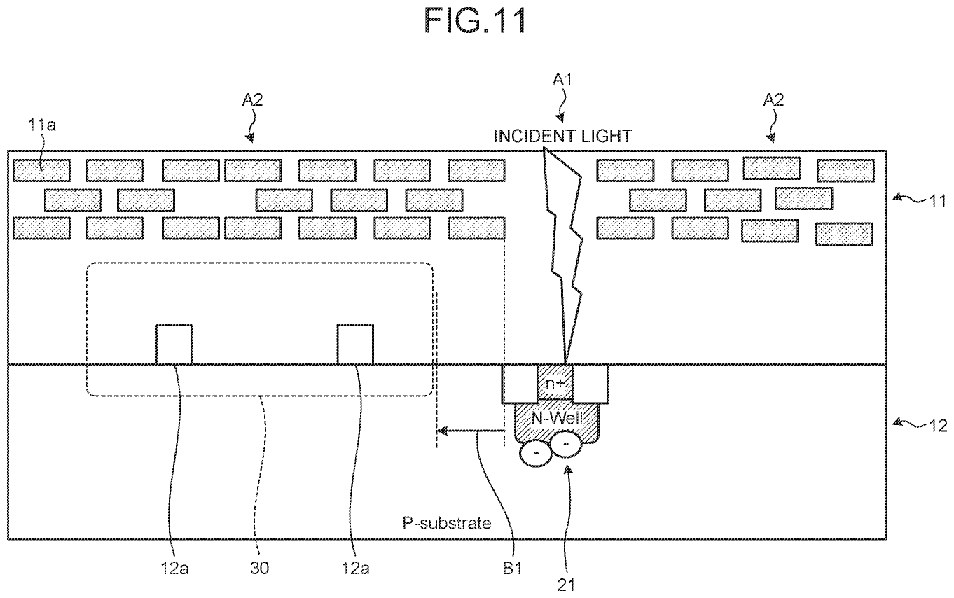

An example of a schematic structure of the semiconductor device 10 according to the embodiment will be described with reference to FIGS. 10 and 11. FIGS. 10 and 11 each illustrate the example of the schematic structure of the semiconductor device 10 according to the embodiment. Differences from the first embodiment will be mainly described below, and other descriptions will be omitted.

As illustrated in FIGS. 10 and 11, the abnormality detecting circuit 30 is provided near the center of the semiconductor device 10 in addition to being provided below the dense region A2 of the wiring layer 11 (see FIG. 11). This can inhibit incident light such as ambient light from the outer periphery of the semiconductor device 10 from reaching the abnormality detecting circuit 30.

In addition, the abnormality detecting circuit 30 is separated from the sparse region A1 by a predetermined distance B1, that is, from the photoelectric conversion section 21 by the predetermined distance B1. The predetermined distance B1 is, for example, within a range of several micrometers to ten micrometers (several micrometers or more and ten micrometers or less).

Here, in consideration of the diffraction component of light from the wiring layer 11, incident light may enter the side of the dense region A2 from the side of the sparse region A1 by approximately at least several times of the incident wavelength. For example, when the incident light is near-infrared light of λ=940 nm, the incident light may enter the side of the dense region A2 from the side of the sparse region A1 by approximately at least several micrometers to ten um. Therefore, the abnormality detecting circuit 30 is preferably provided away from the sparse region A1 by approximately at least several micrometers to ten um.

<5-2. Actions/Effects>

As described above, according to a fifth embodiment, effects similar to those of the first embodiment can be obtained. That is, the configuration according to the fifth embodiment can also inhibit the driving section 40 from performing a driving operation in accordance with a malfunction of the instruction circuit (for example, abnormality detecting circuit 30) due to incident light.

In addition, the instruction circuit may be provided near the center of the semiconductor device 10. This can inhibit incident light from the outer periphery of the semiconductor device 10 from reaching the instruction circuit, so that a malfunction of the instruction circuit can be reliably inhibited.

### 6. SIXTH EMBODIMENT

<6-1. Example of Schematic Structure of Semiconductor Device>

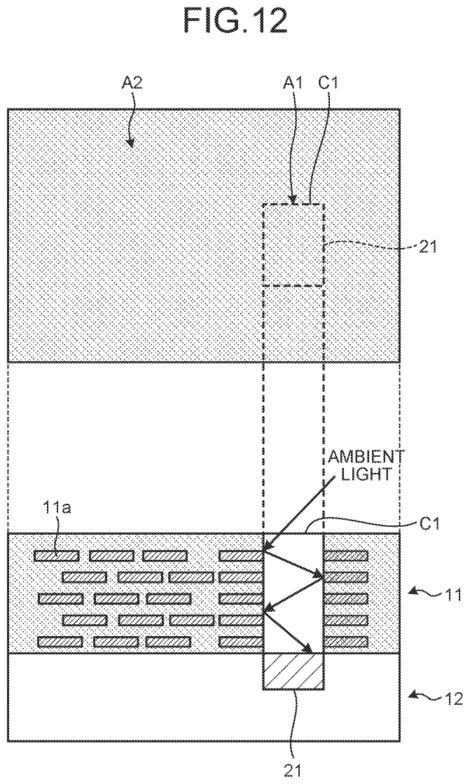

An example of a schematic structure of the semiconductor device 10 according to an embodiment will be described with reference to FIG. 12. FIG. 12 illustrates an example of the schematic structure of the semiconductor device 10 according to the embodiment. Differences from the first embodiment will be mainly described below, and other descriptions will be omitted.

As illustrated in FIG. 12, individual ends of respective pieces of wiring 11a directed to the sparse region A1 of the wiring layer 11 are aligned. Respective pieces of wiring 11a do not enter the sparse region A1. This forms a tubular opening C1. The opening C1 functions as a waveguide that guides incident light. The photoelectric conversion section 21 is provided below (for example, immediately below) the opening C1. This makes it possible to guide incident light such as ambient light to the photoelectric conversion section 21, so that the incident light can be reliably detected.

<6-2. Actions/Effects>

As described above, according to a sixth embodiment, effects similar to those of the first embodiment can be obtained. That is, the configuration according to the sixth embodiment can also inhibit the driving section 40 from performing a driving operation in accordance with a malfunction of the instruction circuit (for example, abnormality detecting circuit 30) due to incident light.

In addition, the wiring layer 11 may have the tubular opening C1 formed in the sparse region A1. The photoelectric conversion section 21 may be provided below the opening C1. This makes it possible to guide incident light to the photoelectric conversion section 21, so that the incident light can be reliably detected.

### 7. SEVENTH EMBODIMENT

<7-1. Example of Schematic Structure of Semiconductor Device>

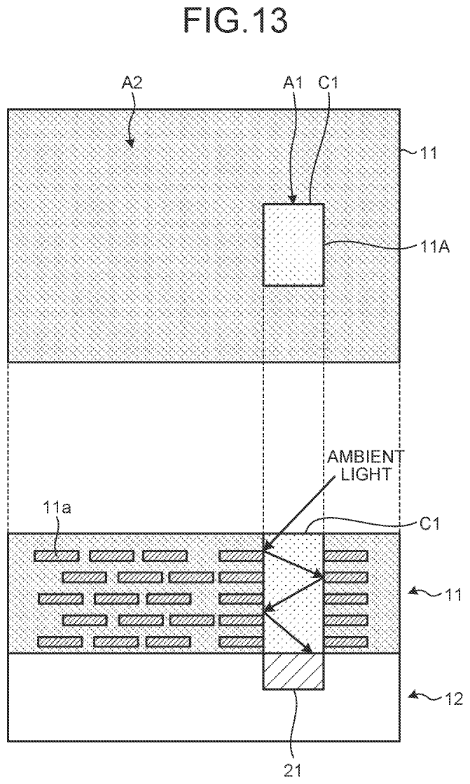

An example of a schematic structure of the semiconductor device 10 according to an embodiment will be described with reference to FIG. 13. FIG. 13 illustrates an example of the schematic structure of the semiconductor device 10 according to the embodiment. Differences from the seventh embodiment will be mainly described below, and other descriptions will be omitted.

As illustrated in FIG. 13, a high refractive index layer 11A is provided in the tubular opening C1. The high refractive index layer 11A has a refractive index higher than that of the wiring layer 11. For example, the tubular opening C1 is filled with a high refractive index material to form the high refractive index layer 11A. This makes it possible to guide incident light such as ambient light to the photoelectric conversion section 21, so that the incident light can be reliably detected. Incidentally, the upper surface (upper surface in FIG. 13) of the high refractive index layer 11A is exposed from the wiring layer 11.

Incident light can be confined by using, for example, a material having a refractive index higher than that of a surrounding SiO2 film as the high refractive index material. Specifically, examples of a metal oxide material used for the high refractive index layer 11A include SiN (1.9 to 2.0), TiO2 (n=2.3 to 2.4), ZrO2 (n=2.1 to 2.2), and Ta2O5 (n=2.1 to 2.2).

<7-2. Actions/Effects>

As described above, according to a seventh embodiment, effects similar to those of the first and sixth embodiments can be obtained. That is, the configuration according to the seventh embodiment can also inhibit the driving section 40 from performing a driving operation in accordance with a malfunction of the instruction circuit (for example, abnormality detecting circuit 30) due to incident light. This further makes it possible to guide incident light to the photoelectric conversion section 21, so that the incident light can be reliably detected.

In addition, the wiring layer 11 may have the high refractive index layer 11A provided in the opening C1. This makes it possible to reliably guide incident light to the photoelectric conversion section 21, so that the incident light can be more reliably detected.

### 8. OTHER EMBODIMENTS

The processing according to the above-described embodiments (or variations) may be carried out in various different forms (variations) other than the above-described embodiments. For example, among pieces of processing described in each of the above-described embodiments, all or part of the processing described as being performed automatically can be performed manually, or all or part of the processing described as being performed manually can be performed automatically by a known method. In addition, the processing procedures, specific names, and information including various pieces of data and parameters in the above document and drawings can be optionally changed unless otherwise specified. For example, various pieces of information in each figure are not limited to the illustrated information.

In addition, each component of each illustrated device is functional and conceptual, and does not necessarily need to be physically configured as illustrated. That is, the specific form of distribution/integration of each device is not limited to the illustrated form, and all or part of the device can be configured in a functionally or physically distributed/integrated manner in any unit in accordance with various loads and use situations.

In addition, the above-described embodiments (or variations) can be appropriately combined as long as the processing contents do not contradict each other. In addition, the effects set forth in the present specification are merely examples and not limitations. Other effects may be exhibited.

### 9. APPLICATION EXAMPLES

The semiconductor device 10 according to each of the above-described embodiments can be applied to various electronic devices, such as a distance measuring device and an imaging device (for example, imaging device including digital still camera and digital video camera, mobile telephone having imaging function, and other devices having imaging function).

<9-1. Distance Measuring Device>

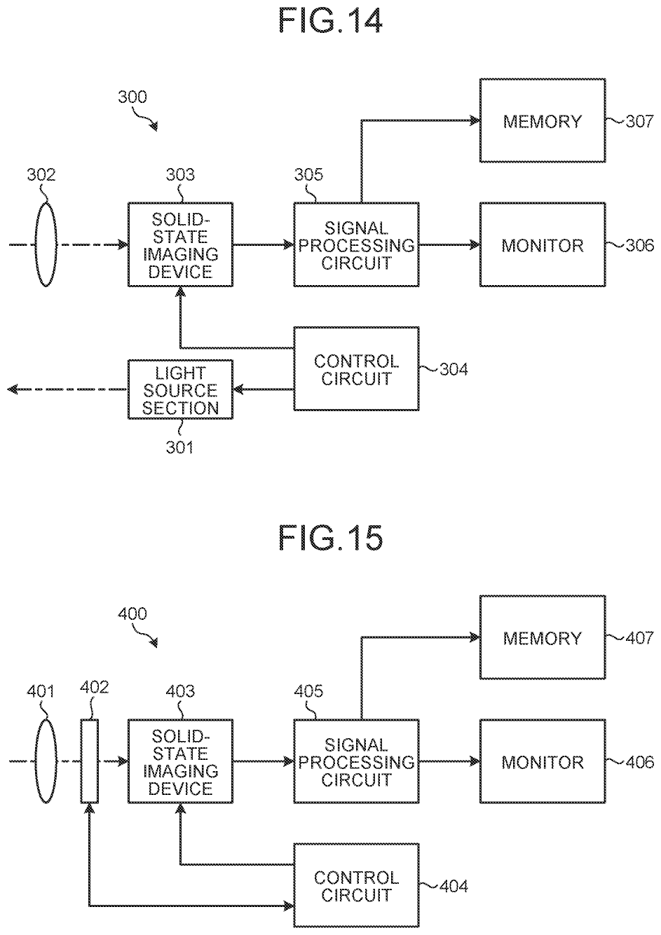

A distance measuring device 300 will be described with reference to FIG. 14. FIG. 14 illustrates an example of a schematic configuration of the distance measuring device 300 serving as an electronic device to which the present technology is applied.

As illustrated in FIG. 14, the distance measuring device (distance image sensor) 300 includes a light source section 301, an optical system 302, a solid-state imaging device (imaging element) 303, a control circuit (driving circuit) 304, a signal processing circuit 305, a monitor 306, and a memory 307. The distance measuring device 300 can acquire a distance image in accordance with a distance to a subject by projecting light from the light source section 301 toward the subject and receiving light (modulated light or pulsed light) reflected on the surface of the subject.

The light source section 301 projects light toward the subject. Examples of the light source section 301 include a vertical cavity surface emitting laser (VCSEL) array and a laser diode array. The VCSEL array emits a laser beam as a surface light source. In the laser diode array, laser diodes are arranged on a line. Incidentally, the laser diode array is supported by a predetermined driving section (not illustrated), and scanned in a direction perpendicular to the arrangement direction of the laser diodes.

The optical system 302 includes one or a plurality of lenses. The optical system 302 guides light (incident light) from a subject to the solid-state imaging device 303, and forms an image of the light on a light receiving surface (sensor section) of the solid-state imaging device 303.

The solid-state imaging device 303 accumulates signal charges in accordance with light whose image is formed on the light receiving surface via an optical system 401. A distance signal indicating a distance determined from a light reception signal (APD OUT) output from the solid-state imaging device 303 is supplied to the signal processing circuit 305. Examples of the solid-state imaging device 303 include a solid-state imaging element such as an image sensor.

The control circuit 304 outputs a drive signal (control signal) for controlling operations of the light source section 301, the solid-state imaging device 303, and the like, and drives the light source section 301, the solid-state imaging device 303, and the like. The control circuit 304 includes the semiconductor device 10 according to any of the embodiments.

The signal processing circuit 305 performs various types of signal processing on a distance signal supplied from the solid-state imaging device 303. For example, the signal processing circuit 305 performs image processing of constructing a distance image (for example, histogram processing and peak detection processing) based on the distance signal. A distance image (image data) obtained by the image processing is supplied to be displayed on the monitor 306, or supplied to be stored (recorded) in the memory 307.

Also in the distance measuring device 300 configured as described above, execution of control in accordance with a malfunction of an instruction circuit can be inhibited by providing the semiconductor device 10 according to any of the embodiments as a part of the control circuit 304.

<9-2. Imaging Device>

An imaging device 400 will be described with reference to FIG. 15. FIG. 15 is a block diagram illustrating a configuration example of the imaging device 400 serving as an electronic device to which the present technology is applied.

As illustrated in FIG. 15, the imaging device 400 includes the optical system 401, a shutter device 402, a solid-state imaging device (imaging element) 403, a control circuit (driving circuit) 404, a signal processing circuit 405, a monitor 406, and a memory 407. The imaging device 400 can capture a still image and a moving image.

The optical system 401 includes one or a plurality of lenses. The optical system 401 guides light (incident light) from a subject to the solid-state imaging device 403, and forms an image of the light on a light receiving surface of the solid-state imaging device 403.

The shutter device 402 is disposed between the optical system 401 and the solid-state imaging device 403. The shutter device 402 controls a light application period and a light shielding period for the solid-state imaging device 403 under the control of the control circuit 404.

The solid-state imaging device 403 accumulates signal charges for a certain period in accordance with light whose image is formed on the light receiving surface via the optical system 401 and the shutter device 402. The signal charges accumulated in the solid-state imaging device 403 are transferred in accordance with a drive signal (timing signal) supplied from the control circuit 404. Examples of the solid-state imaging device 403 include a solid-state imaging element such as an image sensor.

The control circuit 404 outputs a drive signal (control signal) for controlling transfer operation of the solid-state imaging device 403 and shutter operation of the shutter device 402 to drive the solid-state imaging device 403 and the shutter device 402. The control circuit 404 includes the semiconductor device 10 according to any of the embodiments.

The signal processing circuit 405 performs various types of signal processing on the signal charges output from the solid-state imaging device 403. An image (image data) obtained by signal processing performed by the signal processing circuit 405 is supplied to be displayed on the monitor 406, or supplied to be stored (recorded) in the memory 407.

Also in the imaging device 400 configured as described above, the execution of control in accordance with a malfunction of an instruction circuit can be inhibited by providing the semiconductor device 10 according to any of the embodiments as a part of the control circuit 404.

### 10. APPLICATION EXAMPLES

The technology according to the present disclosure can be applied to various products. For example, the technology according to the present disclosure may be achieved as a device mounted in any type of mobile body, such as an automobile, an electric vehicle, a hybrid electric vehicle, a motorcycle, a bicycle, a personal mobility, an airplane, a drone, a ship, a robot, a construction machine, and an agricultural machine (tractor).

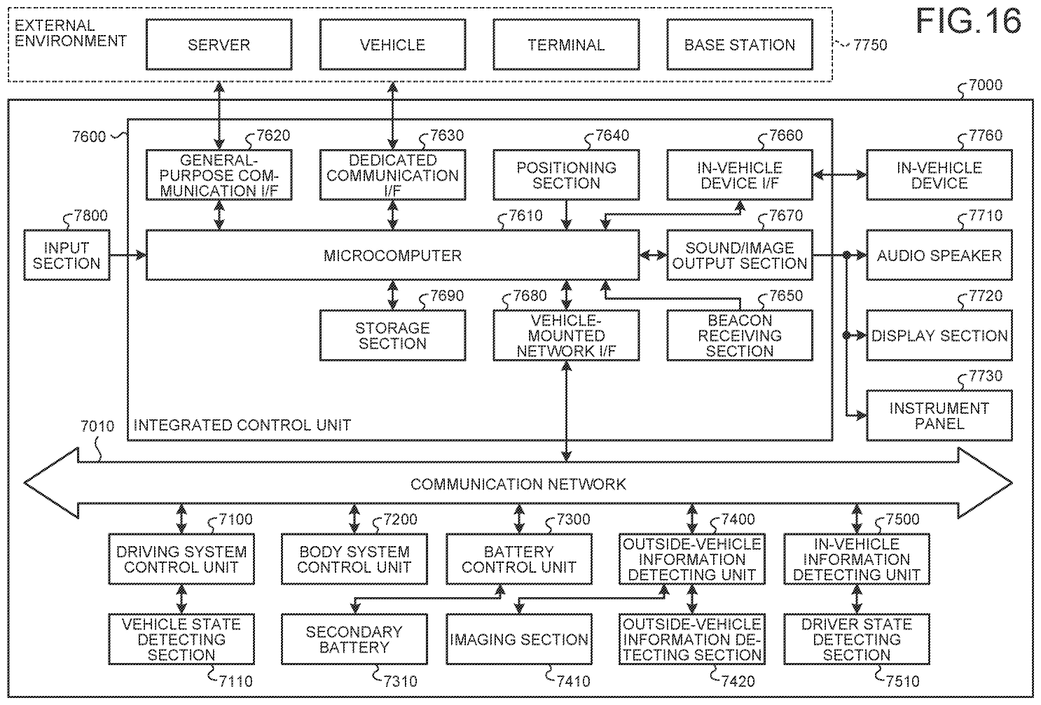

FIG. 16 is a block diagram depicting an example of schematic configuration of a vehicle control system 7000 as an example of a mobile body control system to which the technology according to an embodiment of the present disclosure can be applied. The vehicle control system 7000 includes a plurality of electronic control units connected to each other via a communication network 7010. In the example in FIG. 16, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various devices to be driven. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 illustrated in FIG. 16 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

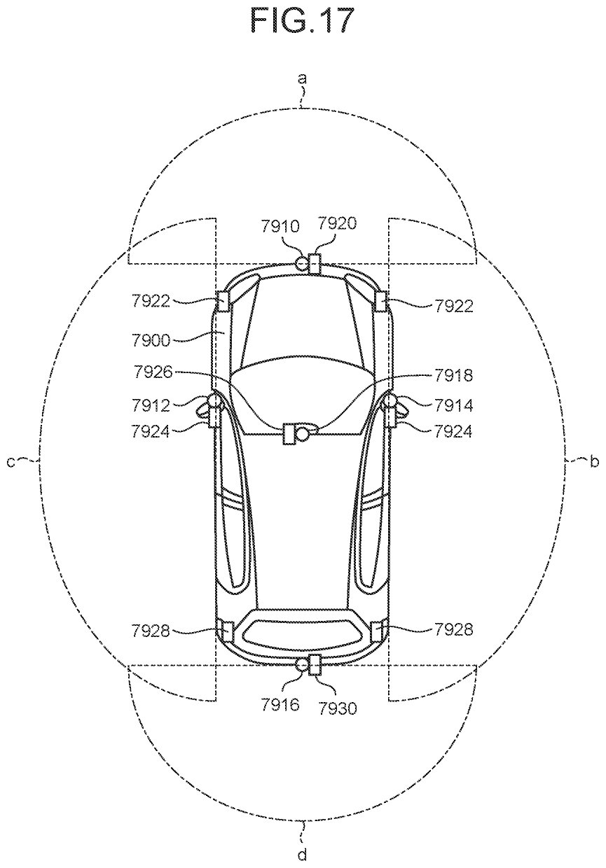

FIG. 17 depicts an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Incidentally, FIG. 17 depicts an example of photographing ranges of the respective imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 16, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 16, an audio speaker 7710, a display section 7720, and an instrument panel 7730 are illustrated as the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Incidentally, at least two control units connected to each other via the communication network 7010 in the example depicted in FIG. 16 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

Incidentally, a computer program for implementing the functions of the distance measuring device 300 and the imaging device 400 including the semiconductor device 10 described in the embodiments (including variations) can be implemented in any control unit and the like. In addition, a computer-readable recording medium storing such a computer program can be provided. The recording medium is, for example, a magnetic disk, an optical disk, a magneto-optical disk, and a flash memory. In addition, the above-described computer program may be distributed via, for example, a network without using a recording medium.

In the above-described vehicle control system 7000, the distance measuring device 300 and the imaging device 400 including the semiconductor device 10 described in the embodiments (including variations) can be applied to the integrated control unit 7600 of an application example in FIG. 16. For example, the control circuit 304 and the memory 307 of the distance measuring device 300 and the control circuit 404 and the memory 407 of the imaging device 400 may be implemented by the microcomputer 7610 and the storage section 7690 of the integrated control unit 7600. In addition, the distance measuring device 300 and the imaging device 400 including the semiconductor device 10 described in the embodiments (including variations) can be applied to the imaging section 7410 and the outside-vehicle information detecting section 7420 in the application example in FIG. 16, for example, the imaging sections 7910, 7912, 7914, 7916, and 7918 and the outside-vehicle information detecting sections 7920 to 7930 of an application example in FIG. 17. The execution of control in accordance with a malfunction of an instruction circuit can be inhibited by using the distance measuring device 300 and the imaging device 400 including the semiconductor device 10 described in the embodiments (including variations).

In addition, at least some components of the distance measuring device 300 and the imaging device 400 including the semiconductor device 10 described in the embodiments (including variations) may be implemented in a module (for example, integrated circuit module including one die) for the integrated control unit 7600 of the application example in FIG. 16. Alternatively, a part of the distance measuring device 300 and the imaging device 400 including the semiconductor device 10 described in each of the embodiments may be implemented by a plurality of control units of the vehicle control system 7000 in FIG. 16.

### 11. APPENDIX

Incidentally, the present technology can also have the configurations as follows.
(1)
A semiconductor device comprising:
a driving section that drives an object to be driven;
an instruction circuit that outputs an instruction signal to the driving section; and
a light amount detecting section that detects an amount of incident light, and invalidates the instruction signal output from the instruction circuit in accordance with the amount of incident light.
(2)
The semiconductor device according to (1),
wherein the light amount detecting section sets the driving section into a waiting state in accordance with the amount of incident light, and invalidates the instruction signal output from the instruction circuit.
(3)
The semiconductor device according to (1) or (2),
wherein the light amount detecting section includes a photoelectric conversion section that performs photoelectric conversion; and
the photoelectric conversion section is provided around the instruction circuit.
(4)
The semiconductor device according to (3),
wherein the photoelectric conversion section is provided at a position adjacent to the instruction circuit.
(5)
The semiconductor device according to (3),
wherein the photoelectric conversion section is annularly formed so as to surround an outer periphery of the instruction circuit.
(6)
The semiconductor device according to (5),
wherein the photoelectric conversion section is formed so as to cover the instruction circuit from below or above in addition to the outer periphery of the instruction circuit.
(7)
The semiconductor device according to any one of (1) to (6), further comprising
a wiring layer including a sparse region, which is a portion having sparse wiring,
wherein the light amount detecting section includes a photoelectric conversion section that performs photoelectric conversion, and
the photoelectric conversion section is provided below the sparse region.
(8)
The semiconductor device according to (7), further comprising an element layer including the instruction circuit,
wherein the photoelectric conversion section is provided in the element layer below the sparse region.
(9)
The semiconductor device according to (7),
wherein the wiring layer includes an opening having a tubular shape formed in the sparse region, and
the photoelectric conversion section is provided below the opening.
(10)
The semiconductor device according to (9),
wherein the wiring layer includes a high refractive index layer provided in the opening and having a refractive index higher than a refractive index of the wiring layer.
(11)
The semiconductor device according to any one of (1) to (11), further comprising
a wiring layer including a dense region, which is a portion having dense wiring,
wherein the instruction circuit is provided below the dense region.
(12)
The semiconductor device according to any one of (1) to (11), further comprising
a wiring layer having wiring,
wherein the light amount detecting section includes a photoelectric conversion section that performs photoelectric conversion, and
the photoelectric conversion section is stacked on the wiring layer.
(13)
The semiconductor device according to (12),
wherein the photoelectric conversion section includes:
a photoelectric conversion film that performs photoelectric conversion; and
a pair of electrode films provided so as to sandwich the photoelectric conversion film,
an electrode film on a side of the wiring layer among the pair of electrode films includes light blocking property, and
the instruction circuit is provided below the photoelectric conversion section.
(14)
The semiconductor device according to any one of (1) to (13),
wherein the light amount detecting section includes:
a photoelectric conversion section that performs photoelectric conversion; and
a monitor section that observes current generated by the photoelectric conversion section.
(15)
The semiconductor device according to (14), further comprising
a wiring layer including wiring,
wherein the monitor section is provided in the wiring layer.
(16)
The semiconductor device according to any one of (1) to (15),
wherein the driving section drives a semiconductor laser, which is the object to be driven.
(17)
The semiconductor device according to any one of (1) to (16),
wherein the instruction circuit is an abnormality detecting circuit that detects an abnormality related to any of temperature, current, and voltage.
(18)
The semiconductor device according to any one of (1) to (16),
wherein the instruction circuit is a control circuit that controls any of temperature, current, and voltage.
(19)
An electronic device comprising:
a solid-state imaging device; and
a semiconductor device,
wherein the semiconductor device includes:
a driving section that drives an object to be driven;
an instruction circuit that outputs an instruction signal to the driving section; and
a light amount detecting section that detects an amount of incident light, and invalidates the instruction signal output from the instruction circuit in accordance with the amount of incident light.
(20)
A method of controlling a semiconductor device, comprising:
detecting an amount of incident light; and
invalidating an instruction signal output from an instruction circuit to a driving section that controls an object to be driven in accordance with the amount of incident light which has been detected.
(21)
An electronic device including the semiconductor device according to any one of (1) to (18).
(22)
A method of controlling a semiconductor device, comprising controlling the semiconductor device according to any one of (1) to (18).

### REFERENCE SIGNS LIST

10 SEMICONDUCTOR DEVICE
11 WIRING LAYER
11A HIGH REFRACTIVE INDEX LAYER
11a WIRING
12 ELEMENT LAYER
12a ELEMENT
20 LIGHT AMOUNT DETECTING SECTION
21 PHOTOELECTRIC CONVERSION SECTION
21a PHOTOELECTRIC CONVERSION FILM
21b ELECTRODE FILM
21c ELECTRODE FILM
22 MONITOR SECTION
30 ABNORMALITY DETECTING CIRCUIT
40 DRIVING SECTION
300 DISTANCE MEASURING DEVICE
301 LIGHT SOURCE SECTION
302 OPTICAL SYSTEM
303 SOLID-STATE IMAGING DEVICE
304 CONTROL CIRCUIT
305 SIGNAL PROCESSING CIRCUIT
306 MONITOR
307 MEMORY
400 IMAGING DEVICE
401 OPTICAL SYSTEM
402 SHUTTER DEVICE
403 SOLID-STATE IMAGING DEVICE
404 CONTROL CIRCUIT
405 SIGNAL PROCESSING CIRCUIT
406 MONITOR
407 MEMORY
A1 SPARSE REGION
A2 DENSE REGION
B1 PREDETERMINED DISTANCE
C1 OPENING

1. A semiconductor device comprising:
a driving section that drives an object to be driven;
an instruction circuit that outputs an instruction signal to the driving section; and
a light amount detecting section that detects an amount of incident light, and invalidates the instruction signal output from the instruction circuit in accordance with the amount of incident light.

2. The semiconductor device according to claim 1,
wherein the light amount detecting section sets the driving section into a waiting state in accordance with the amount of incident light, and invalidates the instruction signal output from the instruction circuit.

3. The semiconductor device according to claim 1,
wherein the light amount detecting section includes a photoelectric conversion section that performs photoelectric conversion; and
the photoelectric conversion section is provided around the instruction circuit.

4. The semiconductor device according to claim 3,
wherein the photoelectric conversion section is provided at a position adjacent to the instruction circuit.

5. The semiconductor device according to claim 3,
wherein the photoelectric conversion section is annularly formed so as to surround an outer periphery of the instruction circuit.

6. The semiconductor device according to claim 5,
wherein the photoelectric conversion section is formed so as to cover the instruction circuit from below or above in addition to the outer periphery of the instruction circuit.

7. The semiconductor device according to claim 1, further comprising
a wiring layer including a sparse region, which is a portion having sparse wiring,
wherein the light amount detecting section includes a photoelectric conversion section that performs photoelectric conversion, and
the photoelectric conversion section is provided below the sparse region.

8. The semiconductor device according to claim 7, further comprising an element layer including the instruction circuit,
wherein the photoelectric conversion section is provided in the element layer below the sparse region.

9. The semiconductor device according to claim 7,
wherein the wiring layer includes an opening having a tubular shape formed in the sparse region, and
the photoelectric conversion section is provided below the opening.

10. The semiconductor device according to claim 9,
wherein the wiring layer includes a high refractive index layer provided in the opening and having a refractive index higher than a refractive index of the wiring layer.

11. The semiconductor device according to claim 1, further comprising
a wiring layer including a dense region, which is a portion having dense wiring,
wherein the instruction circuit is provided below the dense region.

12. The semiconductor device according to claim 1, further comprising
a wiring layer having wiring,
wherein the light amount detecting section includes a photoelectric conversion section that performs photoelectric conversion, and
the photoelectric conversion section is stacked on the wiring layer.

13. The semiconductor device according to claim 12,
wherein the photoelectric conversion section includes:
a photoelectric conversion film that performs photoelectric conversion; and
a pair of electrode films provided so as to sandwich the photoelectric conversion film,
an electrode film on a side of the wiring layer among the pair of electrode films includes light blocking property, and
the instruction circuit is provided below the photoelectric conversion section.

14. The semiconductor device according to claim 1,
wherein the light amount detecting section includes:
a photoelectric conversion section that performs photoelectric conversion; and
a monitor section that observes current generated by the photoelectric conversion section.

15. The semiconductor device according to claim 14, further comprising
a wiring layer including wiring,
wherein the monitor section is provided in the wiring layer.

16. The semiconductor device according to claim 1,
wherein the driving section drives a semiconductor laser, which is the object to be driven.

17. The semiconductor device according to claim 1,
wherein the instruction circuit is an abnormality detecting circuit that detects an abnormality related to any of temperature, current, and voltage.

18. The semiconductor device according to claim 1,
wherein the instruction circuit is a control circuit that controls any of temperature, current, and voltage.

19. An electronic device comprising:
a solid-state imaging device; and
a semiconductor device,
wherein the semiconductor device includes:
a driving section that drives an object to be driven;
an instruction circuit that outputs an instruction signal to the driving section; and
a light amount detecting section that detects an amount of incident light, and invalidates the instruction signal output from the instruction circuit in accordance with the amount of incident light.

20. A method of controlling a semiconductor device, comprising:
detecting an amount of incident light; and
invalidating an instruction signal output from an instruction circuit to a driving section that controls an object to be driven in accordance with the amount of incident light which has been detected.
